(19) United States
(12) Patent Application Publication
(10) Pub. No.: US 2025/0241113 A1
(43) Pub. Date: Jul. 24, 2025

(54) FILM, OPTOELECTRONIC DEVICE, AND DISPLAY DEVICE

(71) Applicant: TCL Technology Group Corporation, Huizhou (CN)

(72) Inventors: Mi YUAN, Huizhou (CN); Zizhe LU, Huizhou (CN)

(73) Assignee: TCL Technology Group Corporation, Huizhou (CN)

(21) Appl. No.: 19/026,477

(22) Filed: Jan. 17, 2025

(30) Foreign Application Priority Data
Jan. 24, 2024 (CN) 202410102551.2

(51) Int. Cl. H10K 50/115; H10K 50/16; H10K 50/828; H10K 85/60; H10K 102/10

(52) U.S. Cl. CPC H10K 50/115; H10K 50/16; H10K 50/828; H10K 85/654; H10K 85/655; H10K 2102/102; H10K 2102/103

(57) ABSTRACT

The present disclosure provides a film, an optoelectronic device, and a display device. The film includes a first modified material and an N-type semiconductor material, and the first modified material includes at least one of maleimide and a maleimide derivative. The first modified material may function as an electron acceptor because of the small electron density (electron deficiency), and the N-type semiconductor material may function as an electron carrier because of the better conductivity. Electrons are easily transferred from the electron carrier to the electron acceptor, that is, electrons are easy to flow between the N-type semiconductor material and the first modified material, thereby the film may have better electron transport performance. When the film is applied to the optoelectronic device, the electrical performance of the optoelectronic device may be improved.

This application claims priority to Chinese Application No. 202410102551.2, entitled “FILM AND PREPARATION METHOD THEREOF, OPTOELECTRONIC DEVICE, AND DISPLAY DEVICE”, filed on Jan. 24, 2024. The entire disclosures of the above application are incorporated herein by reference.

### TECHNICAL FIELD

The present disclosure relates to a field of film technologies, and more particularly, to a film, an optoelectronic device, and a display device.

### BACKGROUND

Optoelectronic devices include OLED (Organic Light-Emitting Diode) and QLED (Quantum Dot Light Emitting Diode). QLED has the advantages of high color saturation, wettable preparation and high stability, which makes the research of QLED attract more and more attention. OLED has been widely used in display, lighting, smart wear and other fields because of its good self-luminous characteristics, high contrast, fast response and flexible display.

The electron transport layer is an important film layer in the optoelectronic devices device and assumes the function of transporting electrons into the light-emitting layer. However, due to the poor electron transport performance of the existing electron transport layer, the amount of electrons injected into the light-emitting layer is little, which leads to the problem of carrier imbalance in the light-emitting layer, and the electrical performance of the optoelectronic device is poor.

### Technical Solution

In view of this, the present disclosure provides a film, an optoelectronic device, and a display device.

First aspect, embodiments of the present disclosure provides a film comprising a first modified material and an N-type semiconductor material. The first modified material includes at least one of maleimide and a maleimide derivative.

In some embodiments of the present disclosure, the maleimide derivative includes at least one of N-benzylmaleimide, N-phenylmaleimide, N-(1-pyrenyl) maleimide, 9-maleimidoacridine, N-Succinimidyl 3-maleimidopropionate, N-(4-nitrophenyl) maleimide, N-(4-fluoro-phenyl) maleimide, 3,4-dibromomaleimide, 6-Maleimidocaproic acid, and 4-maleimidobutyric acid.

In some embodiments of the present disclosure, the film has a single-layer structure, and the film includes a mixture of the first modified material and the N-type semiconductor material.

In some embodiments of the present disclosure, a mass ratio of the first modified material to the N-type semiconductor material is (1-5):30.

In some embodiments of the present disclosure, the film includes a mixture of the first modified material, the N-type semiconductor material, and a second modified material, and the second modified material includes at least one of fulvalene and a fulvalene derivative.

In some embodiments of the present disclosure, a mass ratio of the first modified material to the N-type semiconductor material to the second modified material is (1-5):30:(1-5).

In some embodiments of the present disclosure, the film includes a first sublayer and a second sublayer stacked in this order, the first sublayer includes the N-type semiconductor material, and the second sublayer includes the first modified material.

In some embodiments of the present disclosure, a thickness ratio of the second sublayer to the first sublayer is (1-5):30.

In some embodiments of the present disclosure, the film include a third sublayer, a first sublayer and a second sublayer stacked in this order, the first sublayer includes the N-type semiconductor material, the second sublayer includes the first modified material, and the third sublayer includes a second modified material, and the second modified material includes at least one of fulvalene and a fulvalene derivative.

In some embodiments of the present disclosure, a thicknesses ratio of the third sublayer to the first sublayer to the second sublayer is (1-5):30:(1-5).

In some embodiments of the present disclosure, fulvalene derivative includes at least one of tetrathiafulvalene, dimethyltetrathiafulvalene, formyltetrathiafulvalene, 4,4′-diphenyltetrathiafulvalene, tetramethyltetraselenifulvalene, bis(trimethylenedithio) tetrathiafulvalene, and tetrakis (methylthio) tetrathiafulvalene.

In some embodiments of the present disclosure, the N-type semiconductor material includes at least one of a metal oxide, a doped metal oxide, a Group II-VI semiconductor material, a Group III-V semiconductor material, and a Group I-III-VI semiconductor material.

In some embodiments of the present disclosure, the metal oxide is selected from at least one of ZnO, BaO, TiO₂, SnO₂; the metal oxide of the doped metal oxides is selected from at least one of ZnO, TiO₂, and SnO₂, and a doping element of the doped metal is selected from at least one of Al, Mg, Li, In, and Ga; the Group II-VI semiconductor material is selected from at least one of ZnS, ZnSe, and CdS; the Group III-V semiconductor material is selected from at least one of InP and GaP; the Group I-III-VI semiconductor material is selected from at least one of CuInS and CuGaS.

Second aspect, embodiments of the present disclosure further provides an optoelectronic device including an anode and a cathode disposed oppositely, N layers of light-emitting unit layers and N-1 layers of charge generating layers disposed between the anode and the cathode, and between each two adjacent light-emitting unit layers is disposed with one charge generating layer, where N is an integer equal to or greater than 2. Each light-emitting unit layer includes a light-emitting layer and an electron-transporting layer stacked together, and the electron-transporting layer is disposed on a side of the light-emitting layer close to the cathode. At least one electron transport layer between the charge generating layer and the light-emitting layer includes the film described above.

In some embodiments of the present disclosure, the optoelectronic device further includes a hole injection layer and a hole transport layer stacked together, the hole injection layer and the hole transport layer are disposed between one of the light-emitting unit layers closest to the anode and the anode, and the hole transport layer is disposed on a side of the hole injection layer close to the cathode.

In some embodiments of the present disclosure, each of the charge generating layers includes a hole generating layer and an electron generating layer stacked together, and in each of the charge generating layers, and the hole generating layer is disposed on a side of the electron generating layer close to the cathode.

In some embodiments of the present disclosure, the anode and the cathode independently include a doped metal oxide particle electrode, a composite electrode, a graphene electrode, a carbon nanotube electrode, a metal elemental electrode, or an alloy electrode; a material of the doped metal oxide particle electrode includes one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode includes one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS; a material of the metal elemental electrode includes one or more of Ag, Al, Cu, Mo, Au, Pt, Ca, Mg, and Ba.

In some embodiments of the present disclosure, a material of each light-emitting layer independently includes one or more of an organic light-emitting material and a quantum dot light-emitting material; the organic light-emitting material includes one or more of 4,4′-bis(N-carbazole)-1,1′-biphenyl: tris[2-(p-tolyl) pyridinyl iridium (III), 4,4′,4″-tris(carbazol-9-yl) triphenylamine: tris[2-(p-tolyl) pyridinate iridium, diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, thermally activated delayed materials, polymers containing B-N covalent bonds, hybrid local charge transfer excited state materials, exciplex luminescent materials, polyacetylene and derivatives thereof, polyphenylene and derivatives thereof, polythiophene and derivatives thereof; the quantum dot light-emitting material includes one or more of a single structure quantum dot, a core-shell structure quantum dot, and a perovskite semiconductor material; a material of the single structure quantum dot, a material of the core material of the core-shell structure quantum dot, and material of the shell material of the core-shell structure quantum dot are independently selected from one or more of a Group II-VI compound, a Group IV-VI compound, a Group III-V compound, and a Group I-III-VI compound; the Group II-VI compound includes one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the Group IV-VI compound includes one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the Group III-V compound includes GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the Group I-III-VI compound includes one or more of CuInS₂, CuInSe₂, and AgInS₂; the perovskite-type semiconductor material includes a doped or undoped inorganic perovskite-type semiconductor or an organic-inorganic hybrid perovskite-type semiconductor, the general structural formula of the inorganic perovskite-type semiconductor is AMX₃, wherein A is a Cs⁺ ion, M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion including one or more of Cl⁻, Br⁻, and I⁻; a general structural formula of the organic-inorganic hybrid perovskite type semiconductor is BMX₃, where B is an organic amine cation including CH₃(CH₂)ₙ₋₂NH₃⁺ or [NH₃(CH₂)ₙ NH₃]2+, where n≥2, M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion including one or more of Cl⁻, Br⁻, and I⁻.

In some embodiments of the present disclosure, a material of the hole transport layer includes 4,4′-N,N′-dicarbazolyl-biphenyl, poly [bis(4-phenyl) (2,4,6-trimethylphenyl) amine], N,N′-diphenyl-N,N′-bis(1-naphthyl)-1,1′-biphenyl-4,4′-diamine, N,N′-diphenyl-N,N′-bis(3-methylphenyl)-4,4′-diamine, N′-bis(phenyl)-spiro, N,N′-bis(4-(N,N′-diphenyl-amino) phenyl)-N,N′-diphenylbenzidine, 4,4′,4′-tris (N-carbazolyl)-triphenylamine, 4,4′,4′-tris (N-3-methylphenyl-N-phenylamino) triphenylamine, poly [(9,9′-dioctylfluorene-2,7-diyl)-co-(4,4′-(N-(4-sec-butylphenyl)-co-(4,4′-(N-(4-sec-butylphenyl) diphenylamine)], poly(N-vinylcarbazole) and derivatives thereof, 1′-biphenyl-4-4′-diamine, spiro NPB, poly (phenylenevinylene), poly [2-methoxy-5-(2-ethylhexyloxy)-1,4-phenylenevinylene], poly [2-methoxy-5-(3′,7′-dimethyloctoxy)-1,4-phenylenevinylene], 2,2′,7,7′-tetrakis [N,N-bis(4-methoxyphenyl) amino]-9,9′-spirobifluorene, 4,4′-cyclohexylbis [N,N-bis(4-methylphenyl) aniline], 1,3-bis(carbazol-9-yl) benzene, polyaniline, polypyrrole, poly (P) phenylene vinylidene, aromatic tertiary amine, polynuclear aromatic tertiary amine, 4,4′-bis (P-carbazolyl)-1,1′-biphenyl compound, N,N,N′,N′-tetraarylbenzidine, PEDOT:PSS and derivatives thereof, polymethacrylates and derivatives thereof, poly (9,9-octylfluorene) and derivatives thereof, poly (spirofluorene) and derivatives thereof, poly (spirofluorene) and derivatives thereof, doped graphene, undoped graphene, undoped graphene, C60, doped or undoped NiO, doped or undoped MoO₃, doped or undoped WO₃, doped or undoped V₂O₅, doped or undoped P-type gallium nitride, doped or undoped CrO₃, and doped or undoped CuO.

In some embodiments of the present disclosure, a material of the hole injection layer and a material of each hole generating layer each independently include one or more of 2,3,6,7,10,11-hexacyano-1,4,5,8,9,12-hexaazabenzophenanthrene, PEDOT, PEDOT: PSS, a derivative of PEDOT: PSS doped s-MoO₃, 4,4′,4′-tris(N-3-methylphenyl-N-phenylamino) triphenylamine, tetracyanoquinodimethane, copper phthalocyanine, nickel oxide, molybdenum oxide, tungsten oxide, vanadium oxide, molybdenum sulfide, tungsten sulfide, and copper oxide.

Third aspect, embodiments of the present disclosure further provides a display device including the optoelectronic device described above.

The film provided in the embodiments of the present disclosure includes the first modified material, and the first modified material includes at least one of maleimide and a maleimide derivative. The first modified material may function as an electron acceptor because of the small electron density (electron deficiency), and the N-type semiconductor material may function as an electron carrier because of the better conductivity. Electrons are easily transferred from the electron carrier to the electron acceptor, that is, electrons are easy to flow between the N-type semiconductor material and the first modified material, thereby the film may have better electron transport performance.

### BRIEF DESCRIPTION OF DRAWINGS

In order to more clearly explain the technical solutions in the embodiments of the present disclosure, the drawings to be used in the description of the embodiments are briefly described below.

FIG. 1 is a schematic diagram of a first structure of a film according to an embodiment of the present disclosure;

FIG. 2 is a schematic diagram of a second structure of a film according to an embodiment of the present disclosure;

FIG. 3 is a schematic diagram of a third structure of a film according to an embodiment of the present disclosure;

FIG. 4 is a flowchart of a first method of preparing a film according to an embodiment of the present disclosure;

FIG. 5 is a flowchart of a second method of preparing a quantum dot according to an embodiment of the present disclosure.

FIG. 6 is a schematic diagram of an optoelectronic device according to an embodiment of the present disclosure.

### DETAILED DESCRIPTION

Technical solutions in embodiments of the present disclosure will be clearly and completely described below with reference to the drawings in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, and the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural (multiple).

In the present disclosure, another layer is formed “on” a certain layer, and the so-called “on” is a broad concept, which may mean that the other layer is formed adjacent to the certain layer, or may mean that another spacer structure layer exists between the other layer and the certain layer. For example, a second electrode is formed “on” the first carrier functional layer, and the so-called “on” may mean that the second electrode is formed adjacent to the first carrier functional layer, or may mean that another spacer structure layer exists between the second electrode and the first carrier functional layer, for example, a light-emitting layer.

“Parts by weight” refers to a basic unit of measurement representing the mass ratio relationship of a plurality of components, and 1 part may represent any unit mass, for example, 1 g, 1 Kg, 2 g, 2 Kg, and the like. If we say that the parts by weight of component A is a parts and the parts by weight of component B is b parts, then the ratio of the mass of component A to the mass of component B is a:b. Alternatively, the mass of the A component is aK and the mass of the B component is bK (K is an arbitrary number and represents a multiple factor). It cannot be misunderstood that, unlike parts by weight, the sum of parts by weight of all components is not limited to 100 parts.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range.

Referring to FIG. 1, an embodiment of the present disclosure provides a film 61. The film 61 includes a first modified material and an N-type semiconductor material. The first modified material includes at least one of maleimide and a maleimide derivative.

Exemplarily, the maleimide derivative includes at least one of N-benzylmaleimide, N-phenylmaleimide, N-(1-pyrenyl) maleimide, 9-maleimidoacridine, N-Succinimidyl 3-maleimidopropionate, N-(4-nitrophenyl) maleimide, N-(4-fluoro-phenyl) maleimide, 3,4-dibromomaleimide, 6-Maleimidocaproic acid, and 4-maleimidobutyric acid.

Exemplarily, a thickness of the film 61 is 10 nm-60 nm, for example, 10 nm, 15 nm, 20 nm, 25 nm, 30 nm, 35 nm, 40 nm, 45 nm, 50 nm, 60 nm, and the like.

Referring to FIG. 1, the film 61 may have a single-layer structure, and the film 61 includes a mixture of the first modified material and the N-type semiconductor material. A mass ratio of the first modified material to the N-type semiconductor material is (1-5):30, for example, 1:30, 2:30, 3:30, 4:30, 5:30, and the like.

It can be understood that when the material of the film 61 is a composite material, it means that the first modified material and the N-type semiconductor material are mixed with each other. At this time, the first modified material may function as an electron acceptor because of the small electron density (electron deficiency), and the N-type semiconductor material may function as an electron carrier because of the better conductivity. Electrons are easily transferred from the electron carrier to the electron acceptor, that is, electrons are easy to flow between the N-type semiconductor material and the first modified material, thereby the film 61 may have better electron transport performance.

Referring to FIG. 1, the film may have a single-layer structure, and the film includes a mixture of the first modified material, the N-type semiconductor material, and a second modified material. The second modified material includes at least one of fulvalene and a fulvalene derivative. A mass ratio of the first modified material to the N-type semiconductor material to the second modified material is (1-5):30:(1-5), for example, 1:30:1, 2:30:2, 3:30:3, 4:30:4, 5:30:5, 1:30:3, 2:30:5, 2:30:4, and the like.

Exemplarily, the fulvalene derivative may include at least one of tetrathiafulvalene, dimethyltetrathiafulvalene, formyltetrathiafulvalene, 4,4′-diphenyltetrathiafulvalene, tetramethyltetraselenifulvalene, bis(trimethylenedithio) tetrathiafulvalene, and tetrakis (methylthio) tetrathiafulvalene.

It can be understood that when the composite material further includes the second modified material, it means that the composite material simultaneously includes the first modified material, the N-type semiconductor material, and the second modified material. The electron density in the second modified material is larger (that is electron-rich), and the electron density in the first modified material is small (that is electron-deficient), electrons are easily transferred from the second modified material to the first modified material, that is, electrons are easy to flow between the second modified material and the first modified material, thereby the electron transport performance of the film 61 may be improved.

It should be noted that when the composite material further includes the second modified material, since both the fulvalene and the fulvalene derivative may combine with a metal element on the surface of the N-type semiconductor material to form a stable chemical bond, the N-type semiconductor material in the film 61 may be connected to form a stable structure, thereby improving the density of the film 61, improving the solvent resistance of the film 61, and further improving or eliminating the cracking phenomenon of the film 61.

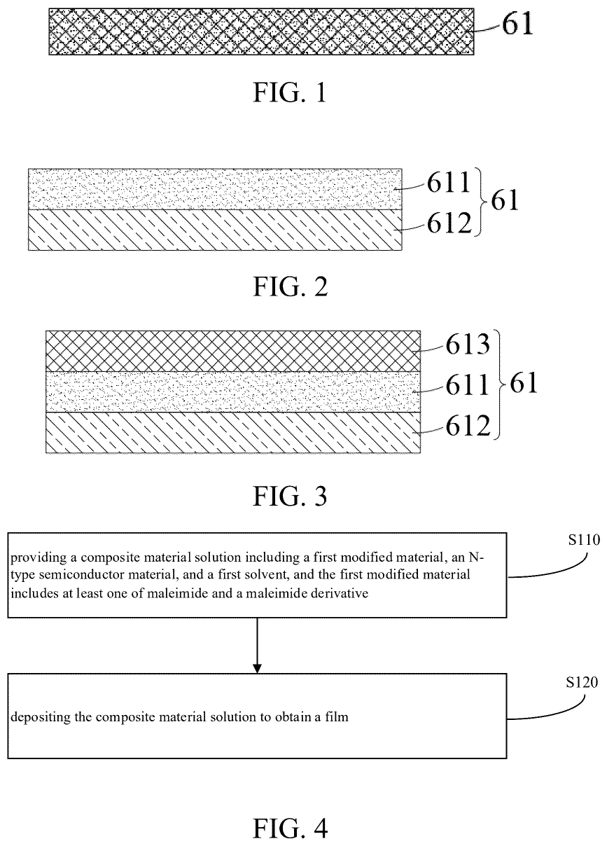

Referring to FIG. 2, the film 61 may include a first sublayer 611 and a second sublayer 612 stacked in this order. The first sublayer 611 includes the N-type semiconductor material, and the second sublayer 612 includes the first modified material. A thickness ratio of the second sublayer 612 to the first sublayer 611 is (1-5):30, for example, 1:30, 2:30, 3:30, 4:30, 5:30, and the like.

It can be understood that when the film 61 includes the first sublayer 611 and the second sublayer 612 stacked in this order, it means that the first modified material and the N-type semiconductor material independently form film layers, respectively. At the interface between the second sublayer 612 and the first sublayer 611, the second sublayer 612 may function as an electron acceptor because of the small electron density (electron deficiency) in the second sublayer 612, while the first sublayer 611 may function as an electron carrier because of the better conductivity. Electrons are easily transferred from the electron carrier to the electron acceptor, that is, electrons are easy to flow between the first sublayer 611 and the second sublayer 612, thereby the film 61 may have better electron transport performance.

Referring to FIG. 3, the film 61 may include a third sublayer 613, a first sublayer 611 and a second sublayer 612 stacked in this order. The first sublayer 611 includes the N-type semiconductor material, the second sublayer 612 includes the first modified material, and the third sublayer 613 includes a second modified material. The second modified material includes at least one of fulvalene and a fulvalene derivative. A thicknesses ratio of the third sublayer 613 to the first sublayer 611 to the second sublayer 612 is (1-5):30:(1-5), for example, 1:30:1, 2:30:2, 3:30:3, 4:30:4, 5:30:5, 1:30:3, 2:30:5, 2:30:4, and the like.

It can be understood that when the film 61 includes the second sublayer 612, the first sublayer 611, and the third sublayer 613 stacked in this order, due to the small electron density (electron deficiency) in the material of the second sublayer 612, and the large electron density (electron-rich) in the material of the third sublayer 613, electrons may easily flow in the direction from the third sublayer 613 to the second sublayer 612, and thus the electron transport performance of the film 61 may be improved. Furthermore, since the material of the third sublayer 613 includes at least one of fulvalene and fulvalene derivatives, and both the fulvalene and the fulvalene derivative may combine with a metal element on the surface of the N-type semiconductor material to form a stable chemical bond, the N-type semiconductor material in the first sublayer 611 may be connected to form a stable structure, thereby improving the density of the film 61, improving the solvent resistance of the film 61, and further improving or eliminating the cracking phenomenon of the film 61.

Exemplarily, the N-type semiconductor material includes at least one of a metal oxide, a doped metal oxide, a Group II-VI semiconductor material, a Group III-V semiconductor material, and a Group I-III-VI semiconductor material. The metal oxide is selected from at least one of ZnO, BaO, TiO₂, SnO₂. The metal oxide of the doped metal oxides is selected from at least one of ZnO, TiO₂, and SnO₂, and a doping element of the doped metal is selected from at least one of Al, Mg, Li, In, and Ga. The Group II-VI semiconductor material is selected from at least one of ZnS, ZnSe, and CdS. The Group III-V semiconductor material is selected from at least one of InP and GaP. The Group I-III-VI semiconductor material is selected from at least one of CuInS and CuGaS.

The material of the film 61 provided by embodiments of the present disclosure includes the first modified material, and the first modified material includes at least one of maleimide and the maleimide derivative, the first modified material may function as an electron acceptor because of the small electron density (electron deficiency), and the N-type semiconductor material may function as an electron carrier because of the better conductivity. Electrons are easily transferred from the electron carrier to the electron acceptor, that is, electrons are easy to flow between the N-type semiconductor material and the first modified material, thereby the film 61 may have better electron transport performance. When the film 61 is applied to an optoelectronic device, the electrical performance of the optoelectronic device may be improved.

Referring to FIG. 4, and in combination with FIG. 1, embodiments of the present disclosure provides a method of preparing a film, the method includes:

S110, providing a composite material solution including a first modified material, an N-type semiconductor material, and a first solvent, and the first modified material includes at least one of maleimide and a maleimide derivative.

S120, depositing the composite material solution to obtain a film 61.

Exemplarily, in the composite material solution, the concentration of the first modified material is 1 mg/mL-5 mg/mL (for example, 1 mg/mL, 2 mg/mL, 3 mg/mL, 4 mg/mL, 5 mg/mL, etc.), and the concentration of the N-type semiconductor material is 10 mg/mL-50 mg/mL (for example, 10 mg/mL, 15 mg/mL, 20 mg/mL, 25 mg/mL, 30 mg/mL, 35 mg/mL, 40 mg/mL, 45 mg/mL, 50 mg/mL, etc.).

It should be noted that the reason why the concentration of the N-type semiconductor material in the composite material solution is set to 10 mg/mL-50 mg/mL is that: when the concentration of the N-type semiconductor material is greater than 50 mg/mL, the phenomenon of agglomeration of the N-type semiconductor material is more likely to occur because the collision of the N-type semiconductor material in the solution is accelerated if the concentration is too high, and when the concentration of the N-type semiconductor material is less than 10 mg/mL, the thickness of the film 61 to be produced may be too thin and the phenomenon of uneven film thickness occurs.

Exemplarily, the first solvent in the composite material solution includes at least one of N,N-dimethylformamide (DMF), N,N-dimethylacetamide (DMEAA), N,N-dimethylpropionamide (DMPA), 1,2-dichloroethane, ethyl acetate, chloroform, dichloromethane, tetrahydrofuran (THF), dinitrotoluene, ethanol, and acetone.

Exemplarily, depositing the composite material solution to obtain a film 61 includes: depositing the composite material solution to obtain a first wet film, performing a first annealing treatment on the first wet film to obtain the film 61. A temperature of the first annealing treatment is 80° C.-120° C. (for example, 80° C., 90° C., 100° C., 110° C., 120° C., etc.), and a time of the first annealing treatment is 5 minutes-10 minutes (for example, 5 minutes, 6 minutes, 7 minutes, 8 minutes, 9 minutes, 10 minutes, etc.).

It should be noted that the reason why the temperature of the first annealing treatment is selected to be 80° C.-120° C. is that: when the temperature is higher than 120° C., ligands on the surface of the N-type semiconductor material (such as zinc oxide nanoparticles) may be inactivated, thereby the steric hindrance may be increased, and the electron transport efficiency may be reduced; when the temperature is lower than 80° C., the solvent in the film 61 may not be completely removed, and the material of the film 61 may be washed when other functional films 61 are subsequently prepared on the film 61.

Exemplarily, the composite material solution further includes a second modified material including at least one of fulvalene and a fulvalene derivative. A concentration of the second modified material in the composite material solution is 1 mg/mL-5 mg/mL (e.g., 1 mg/mL, 2 mg/mL, 3 mg/mL, 4 mg/mL, 5 mg/mL, etc.).

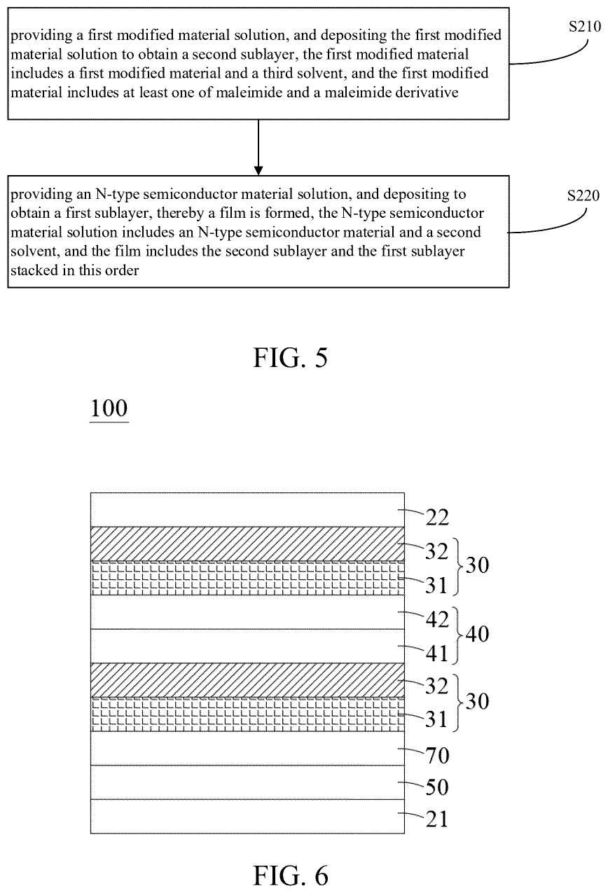

Referring to FIG. 5, and in combination with FIG. 2, an embodiment of the present disclosure provides a method of preparing a film, and the method includes:

S210: providing a first modified material solution, and depositing the first modified material solution to obtain a second sublayer 612, the first modified material includes a first modified material and a third solvent, and the first modified material includes at least one of maleimide and a maleimide derivative.

Exemplarily, a concentration of the first modified material in the first modified material solution is 1 mg/mL-5 mg/mL, for example, 1 mg/mL, 2 mg/mL, 3 mg/mL, 4 mg/mL, 5 mg/mL, etc.

Exemplarily, the third solvent in the first modified material solution includes at least one of N,N-dimethylformamide (DMF), N,N-dimethylacetamide (DMEAA), N,N-dimethylpropionamide (DMPA), 1,2-dichloroethane, ethyl acetate, chloroform, dichloromethane, tetrahydrofuran (THF), dinitrotoluene, ethanol, and acetone.

Exemplarily, a thicknesses ratio of the second sublayer 612 to the first sublayer 611 is (1-5):30, for example, 1:30, 2:30, 3:30, 4:30, 5:30, and the like.

Exemplarily, depositing the first modified material solution to obtain the second sublayer 612 includes: depositing the first modified material solution to obtain a second wet film, and performing annealing treatment on the second wet film to obtain the second sublayer 612. A temperature of the annealing treatment is 80° C.-120° C. (e.g., 80° C., 90° C., 100° C., 110° C., 120° C., etc.), and a time of the annealing treatment is 5 minutes-10 minutes (for example, 5 minutes, 6 minutes, 7 minutes, 8 minutes, 9 minutes, 10 minutes, etc.).

S220, referring to FIG. 2, providing an N-type semiconductor material solution, and depositing to obtain a first sublayer 611, thereby a film 61 is formed. The N-type semiconductor material solution includes an N-type semiconductor material and a second solvent. The film 61 includes the second sublayer 612 and the first sublayer 611 stacked in this order.

It should be noted that the embodiments of the present disclosure do not limit the order of S210 and S220, that is, the second sublayer 612 may be prepared first, or the first sublayer 611 may be prepared first. In some embodiments, the second sublayer 612 is prepared first and then the first sublayer 611 is prepared, thereby an N-type semiconductor material solution is deposited on the second sublayer 612 to obtain the first sublayer 611.

Exemplarily, a concentration of the N-type semiconductor material in the N-type semiconductor material solution is 10 mg/mL-50 mg/mL, for example, 10 mg/mL, 15 mg/mL, 20 mg/mL, 25 mg/mL, 30 mg/mL, 35 mg/mL, 40 mg/mL, 45 mg/mL, 50 mg/mL, and the like.

It should be noted that the reason why the concentration of the N-type semiconductor material in the N-type semiconductor material solution is set to 10 mg/mL-50 mg/mL is that: when the concentration of the N-type semiconductor material is more than 50 mg/mL, the phenomenon of N-type semiconductor material agglomeration is more likely to occur because the collision of the N-type semiconductor material in the solution may be accelerated because the concentration is too high, and when the concentration of the N-type semiconductor material is less than 10 mg/mL, the thickness of the first sublayer 611 may be too thin and the film thickness is uneven.

Exemplarily, the second solvent in the N-type semiconductor material solution includes at least one of methanol, ethanol, isobutanol, isopropanol, and butanol.

Exemplarily, depositing the N-type semiconductor material solution to obtain the first sublayer 611 includes: depositing the N-type semiconductor material solution on the second sublayer 612 to obtain a third wet film, and performing a second annealing treatment on the third wet film to obtain the first sublayer 611. A temperature of the second annealing treatment is 80° C.-120° C. (for example, 80° C., 90° C., 100° C., 110° C., 120° C., etc.), and a time of the second annealing treatment is 5 minutes-10 minutes (for example, 5 minutes, 6 minutes, 7 minutes, 8 minutes, 9 minutes, 10 minutes, etc.).

It should be noted that the reason why the temperature of the second annealing treatment is selected to be 80° C.-120° C. is that: when the temperature is higher than 120° C., ligands on the surface of the N-type semiconductor material (such as zinc oxide nanoparticles) may be inactivated, thereby the steric hindrance may be increased, and the electron transport efficiency may be reduced; when the heating temperature is lower than 80° C., the solvent in the first sublayer 611 may not be completely removed, and the material of the first sublayer 611 may be washed when other functional films 61 are subsequently prepared on the first sublayer 611.

Exemplarily, referring to FIG. 3, the method of preparing the film 61 may further include:

Providing a second modified material solution, and depositing the second modified material solution on the first sublayer 611 to obtain a third sublayer 613. The second modified material solution includes a second modified material and a fourth solvent, and the second modified material includes at least one of fulvalene and fulvalene derivative.

The film 61 includes a second sublayer 612, a first sublayer 611, and a third sublayer 613 stacked in this order.

Referring to FIG. 3, it can be understood that in the film 61, the second sublayer 612 and the third sublayer 613 are respectively provided on both sides of the first sublayer 611. A preparing order of the second sublayer 612, the first sublayer 611, and the third sublayer 613 are not limited in the embodiments of the present disclosure, that is, the film 61 may be prepared in the order in which the second sublayer 612, the first sublayer 611, and the third sublayer 613 are prepared in this order, or in order in which the third sublayer 613, the first sublayer 611, and the second sublayer 612 are produced in this order.

In some embodiments, the film 61 is prepared in the order of sequentially preparing the second sublayer 612, the first sublayer 611, and the third sublayer 613. At this time, the second modified material solution is deposited on the first sublayer 611 to obtain the third sublayer 613.

Exemplarily, a concentration of the second modified material in the second modified material solution is 1 mg/m-5 mg/mL, for example, 1 mg/mL, 2 mg/mL, 3 mg/mL, 4 mg/mL, 5 mg/mL, and the like.

Exemplarily, depositing the second modified material solution on the first sublayer 611 to obtain the third sublayer 613 includes: depositing the second modified material solution on the first sublayer 611 to obtain a fourth wet film, and performing a third annealing treatment on the fourth wet film to obtain the third sublayer 613, A temperature of the third annealing treatment is 80° C.-120° C. (for example, 80° C., 90° C., 100° C., 110° C., 120° C., etc.), and a time of the third annealing treatment is 5 minutes-10 minutes (for example, 5 minutes, 6 minutes, 7 minutes, 8 minutes, 9 minutes, etc.).

Exemplarily, the fourth solvent in the second modified material solution includes at least one of N,N-dimethylformamide (DMF), N,N-dimethylacetamide (DMEAA), N,N-dimethylpropionamide (DMPA), 1,2-dichloroethane, ethyl acetate, chloroform, dichloromethane, tetrahydrofuran (THF), dinitrotoluene, ethanol, and acetone.

Exemplarily, a thicknesses ratio of the third sublayer 613 to the first sublayer 611 to the second sublayer 612 is (1-5):30:(1-5), for example 1:30:1, 2:30:2, 3:30:3, 4:30:4, 5:30:5, 1:30:3, 2:30:4, 1:30:3, 2:30:5, 2:30:4, and the like.

Referring to FIG. 6, and in conjunction with FIG. 1 to FIG. 3, an embodiment of the present disclosure further provides an optoelectronic device 100 including an anode 21 and a cathode 22 disposed oppositely, and N layers of light-emitting unit layers 30 and N-1 layers of charge generating layers 40 disposed between the anode 21 and the cathode 22. Between each two adjacent light-emitting unit layers 30 is disposed with one charge generating layer 40, where N is an integer equal to or greater than 2.

Each light-emitting unit layer 30 includes a light-emitting layer 31 and an electron-transporting layer 32 stacked together, and the electron-transporting layer 32 is disposed on a side of the light-emitting layer 31 close to the cathode 22.

Moreover, at least one electron transport layer 32 disposed between the charge generating layer 40 and the light-emitting layer 31 includes the film 61 in any of the above embodiments or the film 61 prepared by the method of preparing the film 61 in any of the above embodiments.

Referring to FIG. 6, the optoelectronic device 100 further includes a hole injection layer 50 and a hole transport layer 70 stacked together. The hole injection layer 50 and the hole transport layer 70 are disposed between one of the light-emitting unit layers 30 closest to the anode 21 and the anode 21, and the hole transport layer 70 is disposed on a side of the hole injection layer 50 close to the cathode 22.

Each of the charge generating layers 40 includes a hole generating layer 42 and an electron generating layer 41 stacked together. In each of the charge generating layers 40, the hole generating layer 42 is disposed on a side of the electron generating layer 41 close to the cathode 22.

It should be noted that the existing multi-light-emitting layer devices (stacked devices) usually have low charge separation efficiency of the charge generating layer, thus leads to the problems of carrier imbalance and low luminous efficiency inside the multi-light-emitting layer devices (stacked devices). The embodiments of the present disclosure, at least one electron transport layer 32 disposed between the charge generating layer 40 and the light emitting layer 31 includes the film 61, thereby carrier balance inside the multi-light-emitting layer device (stacked device) is promoted, and luminous efficiency of the multi-light-emitting layer device (stacked device) is improved.

Exemplarily, the anode 21 and the cathode 22 independently include a doped metal oxide particle electrode, a composite electrode, a graphene electrode, a carbon nanotube electrode, a metal elemental electrode, or an alloy electrode. A material of the doped metal oxide particle electrode includes one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide. The composite electrode includes one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS. A material of the metal elemental electrode includes one or more of Ag, Al, Cu, Mo, Au, Pt, Ca, Mg, and Ba.

Exemplarily, a material of each light-emitting layer 31 independently includes one or more of an organic light-emitting material and a quantum dot light-emitting material.

The organic light-emitting material includes one or more of 4,4′-bis(N-carbazole)-1,1′-biphenyl: tris[2-(p-tolyl) pyridinyl iridium (III), 4,4′,4″-tris(carbazol-9-yl) triphenylamine: tris[2-(p-tolyl) pyridinate iridium, diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, thermally activated delayed materials, polymers containing B-N covalent bonds, hybrid local charge transfer excited state materials, exciplex luminescent materials, polyacetylene and derivatives thereof, polyphenylene and derivatives thereof, polythiophene and derivatives thereof.

The quantum dot light-emitting material includes one or more of a single structure quantum dot, a core-shell structure quantum dot, and a perovskite semiconductor material.

A material of the single structure quantum dot, a material of the core material of the core-shell structure quantum dot, and material of the shell material of the core-shell structure quantum dot are independently selected from one or more of a Group II-VI compound, a Group IV-VI compound, a Group III-V compound, and a Group I-III-VI compound. The Group II-VI compound includes one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe. The Group IV-VI compound includes one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe. The Group III-V compound includes GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb. The Group I-III-VI compound includes one or more of CuInS₂, CuInSe₂, and AgInS₂.

The perovskite-type semiconductor material includes a doped or undoped inorganic perovskite-type semiconductor or an organic-inorganic hybrid perovskite-type semiconductor, the general structural formula of the inorganic perovskite-type semiconductor is AMX₃, wherein A is a Cs⁺ ion, M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is a halogen anion including one or more of Cl⁻, Br⁻, and I⁻. A general structural formula of the organic-inorganic hybrid perovskite type semiconductor is BMX₃, where B is an organic amine cation including CH₃(CH₂)ₙ₋₂NH₃⁺ or [NH₃(CH₂)ₙNH₃]²⁺, where n≥2, M is a divalent metal cation including one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, Eu²⁺, and X is a halogen anion including one or more of Cl⁻, Br⁻, and I⁻.

Exemplarily, a material of the hole transport layer 70 includes 4,4′-N,N′-dicarbazolyl-biphenyl, poly [bis(4-phenyl) (2,4,6-trimethylphenyl) amine], N,N′-diphenyl-N,N′-bis(1-naphthyl)-1,1′-biphenyl-4,4′-diamine, N,N′-diphenyl-N,N′-bis(3-methylphenyl)-4,4′-diamine, N′-bis(phenyl)-spiro, N,N′-bis(4-(N,N′-diphenyl-amino) phenyl)-N,N′-diphenylbenzidine, 4,4′,4′-tris (N-carbazolyl)-triphenylamine, 4,4′,4′-tris (N-3-methylphenyl-N-phenylamino) triphenylamine, poly [(9,9′-dioctylfluorene-2,7-diyl)-co-(4,4′-(N-(4-sec-butylphenyl)-co-(4,4′-(N-(4-sec-butylphenyl) diphenylamine)], poly(N-vinylcarbazole) and derivatives thereof, 1′-biphenyl-4-4′-diamine, spiro NPB, poly (phenylenevinylene), poly [2-methoxy-5-(2-ethylhexyloxy)-1,4-phenylenevinylene], poly [2-methoxy-5-(3′,7′-dimethyloctoxy)-1,4-phenylenevinylene], 2,2′,7,7′-tetrakis [N,N-bis(4-methoxyphenyl) amino]-9,9′-spirobifluorene, 4,4′-cyclohexylbis [N,N-bis(4-methylphenyl) aniline], 1,3-bis (carbazol-9-yl) benzene, polyaniline, polypyrrole, poly (P) phenylene vinylidene, aromatic tertiary amine, polynuclear aromatic tertiary amine, 4,4′-bis (P-carbazolyl)-1,1′-biphenyl compound, N,N,N′,N′-tetraarylbenzidine, PEDOT:PSS and derivatives thereof, polymethacrylates and derivatives thereof, poly (9,9-octylfluorene) and derivatives thereof, poly (spirofluorene) and derivatives thereof, poly (spirofluorene) and derivatives thereof, doped graphene, undoped graphene, undoped graphene, C60, doped or undoped NiO, doped or undoped MoO₃, doped or undoped WO₃, doped or undoped V₂O₅, doped or undoped P-type gallium nitride, doped or undoped CrO₃, and doped or undoped CuO.

Exemplarily, a material of the hole injection layer 50 and a material of each hole generating layer 42 each independently include one or more of 2,3,6,7,10,11-hexacyano-1,4,5,8,9,12-hexaazabenzophenanthrene, PEDOT, PEDOT: PSS, a derivative of PEDOT: PSS doped s-MoO₃, 4,4′,4′-tris(N-3-methylphenyl-N-phenylamino) triphenylamine, tetracyanoquinodimethane, copper phthalocyanine, nickel oxide, molybdenum oxide, tungsten oxide, vanadium oxide, molybdenum sulfide, tungsten sulfide, and copper oxide.

Referring to FIG. 3, when the film 61 includes the second sublayer 612, the first sublayer 611, and the third sublayer 613 stacked in this order, the second sublayer 612, the first sublayer 611, and the third sublayer 613 are stacked in this order in the direction from the anode 21 to the cathode 22. It should be noted that the electron density in the material of the second sublayer 612 is small, and the electron density in the material of the third sublayer 613 is large (that is electron-rich), so that electrons may easily flow in the direction from the third sublayer 613 to the second sublayer 612, thereby improving the electron transport performance of the film 61. Furthermore, when the thin film 61 is adjacent to the charge generating layer 30, since the thin film 61 has a strong electron transport ability, it is possible to promote the separation of electrons and holes in the charge generating layer 30 and improve the charge separation efficiency, thereby promoting the carrier balance inside the multi-light-emitting layer device (stacked device) and improving the luminous efficiency of the multi-light-emitting layer device (stacked device).

In some embodiments, a material of the electron transport layer 32 closest to the cathode 22 may include at least one of a metal oxide, a doped metal oxide, a Group II-VI semiconductor material, a Group III-V semiconductor material, and a Group I-III-VI semiconductor material. The metal oxide is selected from at least one of ZnO, BaO, TiO₂, SnO₂. The metal oxide of the doped metal oxide is selected from at least one of ZnO, TiO₂, and SnO₂, and the doping element of the doped metal oxide is selected from at least one of Al, Mg, Li, In, and Ga. The Group II-VI semiconductor material is selected from at least one of ZnS, ZnSe, and CdS. The Group III-V semiconductor material is selected from at least one of InP and GaP. The Group I-III-VI semiconductor material is at least one selected from at least one of CuInS and CuGaS.

Exemplarily, a material of the electron generating layer 31 (CGL-N) includes one or more of phosphomolybdic acid (PMA), molybdenum oxide (MoO₃), phosphotungstic acid, and tungsten trioxide (WO₃).

Exemplarily, a thickness of the anode 21 and a thickness of the cathode 22 are each independently 10 nm-120 nm, for example, 10 nm, 20 nm, 30 nm, 40 nm, 50 nm, 60 nm, 70 nm, 80 nm, 90 nm, 100 nm, 110 nm, 120 nm, and the like.

Exemplarily, a thickness of the hole injection layer 50 is 10 nm-50 nm, for example, 10 nm, 20 nm, 30 nm, 40 nm, 50 nm, and the like.

Exemplarily, a thickness of the hole transport layer 70 is 10 nm-50 nm, for example, 10 nm, 20 nm, 30 nm, 40 nm, 50 nm, etc.

Exemplarily, a thickness of the light-emitting layer 31 is 10 nm-50 nm, for example, 10 nm, 20 nm, 30 nm, 40 nm, 50 nm, and the like.

Exemplarily, a thickness of the electron transport layer 32 is 10 nm-50 nm, for example, 10 nm, 20 nm, 30 nm, 40 nm, 50 nm, and the like.

Exemplarily, a thickness of the charge generating layer 40 is 20 nm-70 nm, for example, 20 nm, 30 nm, 40 nm, 50 nm, 60 nm, 70 nm, and the like.

Exemplarily, a thickness of the electron generating layer 41 is 10 nm-20 nm, for example, 10 nm, 12 nm, 15 nm, 18 nm, 20 nm, and the like.

Exemplarily, a thickness of the hole generating layer 42 is 10 nm-50 nm, for example, 10 nm, 20 nm, 30 nm, 40 nm, 50 nm, and the like.

Embodiment of the present disclosure further provides a display device including the optoelectronic device according to any one of the above embodiments or the optoelectronic device prepared by the method of preparing the optoelectronic device according to any one of the above embodiments.

For example, the display device may be a terminal such as a television, a mobile phone, a tablet personal computer, a display, or an advertisement display screen, and may be a device having a display screen such as a game device, an Augmented Reality (AR) device, a Virtual Reality (VR) device, a data storage device, an audio playback device, a video playback device, and a wearable device. The wearable device may be a smart bracelet, smart glasses, a smart watch, a smart decoration, and the like.

Hereinafter, the film of the present disclosure, the preparation method thereof, and the optoelectronic device will be described in detail in the form of specific examples.

### Film Example 1

A film, and a method of preparing the film includes the following steps:

Step 11, providing a composite material solution including a first modified material (N-benzylmaleimide), an N-type semiconductor material (ZMO, ZnMgO) and a first solvent (ethanol), the concentration of the first modified material (N-benzylmaleimide) is 3 mg/mL, and the concentration of the N-type semiconductor material (ZMO) is 30 mg/mL; among them, N-benzylmaleimide was purchased from Aladdin Reagent (Shanghai) Co., Ltd., CAS No. 1631-26-1, the molecular formula is C₁₁H₉NO₂, the molecular weight is 187.2, MDL No. MFCD00014540, and PubChem No. 74204;

Step 12, depositing the composite material solution to obtain a first wet film, and performing annealing treatment on the first wet film (heating at 80° C. for 10 minutes) to obtain a film, the thickness of the film is 40 nm, the film is a single-layer structure, the material of the film includes a mixture of the first modified material and the N-type semiconductor material, and the mass ratio of the first modified material to the N-type semiconductor material is 3:30.

### Film Example 2

A film, and compared with the Film Example 1, the method of preparing the film is different in that:

In step 11, in the composite material solution, the concentration of the first modified material (N-benzylmaleimide) is 1 mg/mL;

In step 12, in the film obtained, the mass ratio of the first modified material to the N-type semiconductor material is 1:30.

### Film Example 3

A film, and compared with the Film Example 1, the method of preparing the film is different in that:

In step 11, in the composite material solution, the concentration of the first modified material (N-benzylmaleimide) is 5 mg/mL;

In step 12, in the film obtained, the mass ratio of the first modified material to the N-type semiconductor material is 5:30.

### Film Example 4

A film, and compared with the Film Example 1, the method of preparing the film is different in that:

In step 11, in the composite material solution, the first modified material is 4-maleimidobutyric acid, and the concentration of the 4-maleimidobutyric acid is 4 mg/mL. N-benzylmaleimide was purchased from Aladdin Reagent (Shanghai) Co., Ltd., CAS No. 1631-26-1, the molecular formula is C₁₁H₉NO₂, the molecular weight is 187.2, MDL No. MFCD00014540, and pubchem No. 74204.

### Film Example 5

A film, and compared with the Film Example 1, the method of preparing the film is different in that:

In step 11, the composite material solution includes a first modified material (N-benzylmaleimide), an N-type semiconductor material (ZMO), a first solvent (ethanol) and a second modified material (4,4′-diphenyltetrathiafulvalene), the concentration of the first modified material (N-benzylmaleimide) is 3 mg/mL, the concentration of the N-type semiconductor material (ZMO) is 30 mg/mL, and the concentration of the second modified material (4,4′-diphenyltetrathiafulvalene) is 3 mg/mL; 4,4′-diphenyltetrathiafulvalene was purchased from Aladdin Reagent (Shanghai) Co., Ltd., CAS No. 5152-94-3, the molecular formula is C₁₈H₁₂S₄, the molecular weight is 356.55,

In step 12, the film prepared includes a mixture of the first modified material, the N-type semiconductor material and the second modified material, and the mass ratio of the first modified material to the N-type semiconductor material to the second modified material is 3:30:3.

### Film Example 6

A film, and compared with the Film Example 5, the method of preparing the film is different in that:

In step 11, in the composite material solution, the concentration of the second modified material (4,4′-diphenyltetrathiafulvalene) is 1 mg/mL;

In step 12, in the film obtained, the mass ratio of the first modified material to the N-type semiconductor material to the second modified material is 3:30:1.

### Film Example 7

A film, and compared with the Film Example 5, the method of preparing the film is different in that:

In step 11, in the composite material solution, the concentration of the second modified material (4,4′-diphenyltetrathiafulvalene) is 5 mg/mL;

In step 12, in the film obtained, the mass ratio of the first modified material to the N-type semiconductor material to the second modified material is 3:30:5.

### Film Example 8

A film, and a method of preparing the film includes the following steps:

Step 21, providing a first modified material solution including a first modified material (N-benzylmaleimide) and a third solvent (ethanol), depositing the first modified material solution to obtain a third wet film, and performing annealing treatment on the third wet film (heating at 80° C. for 10 minutes) to obtain a second sublayer (thickness 36.4 nm);

Step 22, providing an N-type semiconductor material solution including an N-type semiconductor material (ZMO) and a second solvent (ethanol), depositing the N-type semiconductor material solution on the second sublayer to obtain a second wet film, performing annealing treatment on the second wet film (heating at 80° C. for 10 minutes) to obtain a first sublayer (thickness 3.6 nm), thereby a film including the second sublayer and the first sublayer was formed, and the thickness ratio of the second sublayer to the first sublayer is 3:30.

### Film Example 9

A film, and a method of preparing the film includes the following steps:
Step 21, providing a first modified material solution including a first modified material (N-benzylmaleimide) and a third solvent (ethanol), depositing the first modified material solution to obtain a third wet film, and performing annealing treatment on the third wet film (heating at 80° C. for 10 minutes) to obtain a second sublayer (thickness 3.3 nm);
Step 22, providing an N-type semiconductor material solution including an N-type semiconductor material (ZMO) and a second solvent (ethanol), depositing the N-type semiconductor material solution on the second sublayer to obtain a second wet film, and performing annealing treatment on the second wet film (heating at 80° C. for 10 minutes) to obtain a first sublayer (thickness 33.4 nm);
Step 23, providing a second modified material solution including a second modified material (4,4′-diphenyltetrathiafulvalene) and a third solvent (ethanol), depositing the second modified material solution on the first sublayer to obtain a fourth wet film, performing annealing treatment (heating at 80° C. for 10 minutes) on the fourth wet film to obtain a third sublayer (thickness 3.3 nm), thereby a film including the second sublayer, the first sublayer, and the third sublayer which are stacked in this order was formed, and the thicknesses ratio of the second sublayer to the first sublayer to the third sublayer is 3:30:3.

As can be seen, compared with the Film Example 8, the film prepared in the Film Example 9 has a third sublayer disposed on the first sublayer.

### Film Example 10

A film, and compared with the Film Example 1, the method of preparing the film is different in that:

In step 11, in the composite material solution, the concentration of the first modified material (N-benzylmaleimide) is 10 mg/mL;

In step 12, in the film obtained, the mass ratio of the first modified material to the N-type semiconductor material is 10:30.

### Film Example 11

A film, and compared with the Film Example 5, the method of preparing the film is different in that:

In step 11, in the composite material solution, the concentration of the second modified material (4,4′-diphenyltetrathiafulvalene) is 10 mg/mL;

In step 12, in the film obtained, the mass ratio of the first modified material to the N-type semiconductor material to the second modified material is 3:30:10.

### Film Comparative Example 1

A film, and a method of preparing the film includes the following steps:

Providing an N-type semiconductor material solution including an N-type semiconductor material (ZMO) and a solvent (ethanol), and the concentration of the N-type semiconductor material (ZMO) is 30 mg/mL;

Deposited the N-type semiconductor material solution to obtain a wet film, and performing annealing treatment on the wet film (heated at 80° C. for 10 minutes) to obtain a film having a thickness of 40 nm.

### Device Example 1

An optoelectronic device, and a method of preparing the optoelectronic device includes the following steps:
Step S1: treating a washed anode (ITO) with UVO (ultraviolet ozone) for 15 minutes, spin-coating PEDOT: PSS on the anode, and heating at 150° C. for 15 minutes to obtain a hole injection layer, and the thickness of the hole injection layer is 30 nm;
Step S2: spin-coating TFB on the hole injection layer and heating at 150° C. for 15 minutes to obtain a hole transport layer, and the thickness of hole transport layer is 15 nm;
Step S3, spin-coating core-shell structure quantum dots (ZnCdSe/ZnS, ZnCdSe is the core, ZnS is the shell) on the hole transport layer, and heating at 100° C. for 8 minutes to obtain a first light-emitting layer, and the thickness of the first light-emitting layer is 30 nm;
Step S4: forming a film (first electron transport layer) on the first light-emitting layer by the method of Film Example 1;
Step S5: spin-coating PMA on the film to obtain an electron generating layer, and heating at 120° C. for 10 minutes, and the thickness of the electron generating layer is 10 nm;
Step S6: spin-coating TFB onto the electron generating layer to obtain a hole generating layer, heating at 150° C. for 10 minutes, and the thickness of the hole generating layer is 15 nm;
Step S7, spin-coating core-shell structure quantum dots (ZnCdSe/ZnS, ZnCdSe is the core, ZnS is the shell) on the hole generating layer, and heating at 100° C. for 8 minutes to obtain a second light-emitting layer, and the thickness of the second light-emitting layer is 30 nm;
Step S8: spin-coating ZMO nanoparticles on the second light-emitting layer and heating at 80° C. for 10 minutes to obtain a second electron transport layer, and the thickness of the second electron transport layer is 40 nm;
Step S9: vapor-depositing Ag on the second electron transport layer to obtain a cathode, and the thickness of the cathode is 100 nm, thereby an optoelectronic device was obtained.

### Device Example 2

An optoelectronic device, and compared with the Device Example 1, the method of preparing the optoelectronic device is different in that:

In step S4, forming a film (first electron transport layer) on the first light-emitting layer by the method of Film Example 2.

### Device Example 3

An optoelectronic device, and compared with the Device Example 1, the method of preparing the optoelectronic device is different in that:

In step S4, forming a film (first electron transport layer) on the first light-emitting layer by the method of Film Example 3.

### Device Example 4

An optoelectronic device, and compared with the Device Example 1, the method of preparing the optoelectronic device is different in that:

In step S4, forming a film (first electron transport layer) on the first light-emitting layer by the method of Film Example 4.

### Device Example 5

An optoelectronic device, and compared with the Device Example 1, the method of preparing the optoelectronic device is different in that:

In step S4, forming a film (first electron transport layer) on the first light-emitting layer by the method of Film Example 5.

### Device Example 6

An optoelectronic device, and compared with the Device Example 1, the method of preparing the optoelectronic device is different in that:

In step S4, forming a film (first electron transport layer) on the first light-emitting layer by the method of Film Example 6.

### Device Example 7

An optoelectronic device, and compared with the Device Example 1, the method of preparing the optoelectronic device is different in that:

In step S4, forming a film (first electron transport layer) on the first light-emitting layer by the method of Film Example 7.

### Device Example 8

An optoelectronic device, and compared with the Device Example 1, the method of preparing the optoelectronic device is different in that:

In step S4, forming a film (first electron transport layer) on the first light-emitting layer by the method of Film Example 8.

### Device Example 9

An optoelectronic device, and compared with the Device Example 1, the method of preparing the optoelectronic device is different in that:

In step S4, forming a film (first electron transport layer) on the first light-emitting layer by the method of Film Example 9.

### Device Example 10

An optoelectronic device, and compared with the Device Example 1, the method of preparing the optoelectronic device is different in that:

In step S4, forming a film (first electron transport layer) on the first light-emitting layer by the method of Film Example 10.

### Device Example 11

An optoelectronic device, and compared with the Device Example 1, the method of preparing the optoelectronic device is different in that:

In step S4, forming a film (first electron transport layer) on the first light-emitting layer by the method of Film Example 11.

### Device Comparative Example 1

An optoelectronic device, and compared with the Device Example 1, the method of preparing the optoelectronic device is different in that:

In step S4, forming a film (first electron transport layer) on the first light-emitting layer by the method of Comparative Film Example 1.

### Performance Test:

(1) Electron mobility test of films: QE PRO and Keithley 2400 were controlled by LabView, and a QLED efficiency test system was built. The current density-voltage curve of single carrier transport film device (EOD) was tested by this system, and the space charge limiting current (SCLC) region in the curve was obtained through the current density-voltage curve, and then the electron mobility was calculated according to the formula J=(9/8)εr≥0μeV²/d³, where J represents the current density, and having a unit of mAcm⁻²; εᵣ represents the relative dielectric constant and ε₀ represents the vacuum dielectric constant; μₑ represents the electron mobility, and having a unit of cm²V⁻¹s⁻¹; V represents the driving voltage, and having a unit of V; d represents the thickness of the film, and having a unit of unit m. The test results are shown in Table 1.

TABLE 1

| | Electron mobility |
|---|---|
| | (*10⁻⁶cm²V⁻¹s⁻¹) |
| Film Example 1 | 186.35 |
| Film Example 2 | 163.68 |
| Film Example 3 | 186.24 |
| Film Example 4 | 185.17 |
| Film Example 5 | 194.63 |
| Film Example 6 | 190.28 |
| Film Example 7 | 192.33 |
| Film Example 8 | 188.79 |
| Film Example 9 | 191.86 |
| Film Example 10 | 102.16 |
| Film Example 11 | 185.87 |
| Film Comparative Example 1 | 94.35 |

As can be seen from Table 1, the electron mobility of the Film Examples 1-11 are all higher than that of the Film Comparative Example 1, and it is known that the difference between the Film Examples 1-11 and the Film Comparative Example 1 is that: the films prepared in Examples 1-11 of the present disclosure all include ZMO (magnesium doped zinc oxide) nanoparticles and the first modified material (N-benzylmaleimide), while the film of Film Comparative Example 1 is only composed of ZMO (magnesium doped zinc oxide) nanoparticles, which shows that the present disclosure may improve the electron mobility of the film by adding the first modified material (N-benzylmaleimide) to the film, so that the film has better electron transport performance.

(2) The optoelectronic devices prepared in Device Examples 1-11 and Device Comparative Example 1 were tested, and the efficiency test system built by QE PRO spectrometer, Keithley2400 and Keithley6485 was controlled by LabView using Fostar FPD optical characteristic measurement equipment, and parameters such as voltage, current and brightness were measured, and the luminous efficiency CE was calculated. The test results are shown in Table 2 below.

TABLE 2

| | Luminous Eefficiency |
|---|---|
| | (cd/A) |
| Device Example 1 | 22.16 |
| Device Example 2 | 18.31 |
| Device Example 3 | 21.35 |
| Device Example 4 | 21.98 |
| Device Example 5 | 25.52 |
| Device Example 6 | 22.15 |
| Device Example 7 | 24.93 |
| Device Example 8 | 22.31 |
| Device Example 9 | 24.86 |
| Device Example 10 | 12.5 |
| Device Example 11 | 14.37 |
| Device Comparative | 10.59 |
| Example 1 | |

Referring to Table 2 above, it can be seen that the luminous efficiency of the optoelectronic devices of Device Examples 1-11 are greater than that of Device Comparative Example 1, and it is known that the difference between Device Examples 1-11 and Device Comparative Example 1 is only that the material and preparation method of the film (first electron transport layer) are different. The films (first electron transport layer) in Device Examples 1-11 of the present disclosure all include ZMO (magnesium doped zinc oxide) nanoparticles and a first modified material (N-benzylmaleimide), while the film (first electron transport layer) in Device Comparative Example 1 is composed only of ZMO (magnesium doped zinc oxide) nanoparticles. This shows that after the first modified material (N-benzylmaleimide) is added to the film (first electron transport layer) in the present disclosure, the electron transport performance of the film (first electron transport layer) may be improved, and the luminous efficiency of the optoelectronic device may be improved.

By comparing Device Examples 1-3 and Device Example 10, it can be seen that the luminous efficiency of the optoelectronic device of Device Example 10 is significantly lower than that of Device Examples 1-3, and the difference between Device Examples 1-3 and Device Example 10 is known only that: in the film (first electron transport layer) prepared in Device Examples 1-3, the mass ratio of the first modified material to the N-type semiconductor material was (1-5):30, while in the film (first electron transport layer) prepared in Device Example 10, the mass ratio of the first modified material to the N-type semiconductor material was 10:30, it can be seen that, this is because the content of the first modified material (N-benzylmaleimide) in the film (first electron transport layer) prepared in Device Example 10 is too high. It should be noted that when the content of the first modified material (N-benzylmaleimide) in the film is too high, the conductivity of the first modified material (N-benzylmaleimide) is poor, thereby the conductivity of the film (the first electron transport layer) is poor, and the light emission efficiency of the optoelectronic device is affected. In the present disclosure, by controlling the mass ratio of the first modified material to the N-type semiconductor material to (1-5):30, it is possible to ensure that the film (first electron transport layer) has better conductivity, and further ensure that the optoelectronic device has higher luminous efficiency.

By comparing Device Examples 5-7 with Device Example 11, it can be seen that the luminous efficiency of the optoelectronic device of Device Example 11 is significantly lower than that of Device Examples 5-7, and the difference between Device Examples 5-7 and Device Example 11 is known only in that: the mass ratio of the second modified material to the N-type semiconductor material in the film (first electron transport layer) prepared in Device Examples 5-7 is (1-5):30, while the mass ratio of the second modified material to the N-type semiconductor material in the film (first electron transport layer) prepared in Device Example 11 is 10:30, it can be seen that, this is because the excessively high content of the second modified material (4,4′-diphenyltetrathiafulvalene) in the film (first electron transport layer) prepared in Device Example 11, and the second modified material (4,4′-diphenyltetrathiafulvalene) is known to have good conductivity. When the second modified material (4,4′-diphenyltetrathiafulvalene) in the film (first electron transport layer) is too high, the electron concentration in the film (first electron transport layer) will be too large, and the high concentration of electrons will accumulate at the interface between the hole transport layer and the light-emitting layer, causing the organic material in the hole transport layer to be destroyed by electrochemical corrosion, thereby causing the luminous efficiency of the optoelectronic device to decrease. In the present disclosure, by controlling the mass ratio of the second modified material to the N-type semiconductor material to (1-5):30, it is possible to ensure that the optoelectronic device has a high luminous efficiency.

The film, the optoelectronic device, and the display device according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. A film, comprising:
a first modified material and an N-type semiconductor material;
wherein the first modified material comprises at least one of maleimide and a maleimide derivative.

2. The film according to claim 1, wherein the maleimide derivative comprises at least one of N-benzylmaleimide, N-phenylmaleimide, N-(1-pyrenyl) maleimide, 9-maleimidoacridine, N-Succinimidyl 3-maleimidopropionate, N-(4-nitrophenyl) maleimide, N-(4-fluoro-phenyl) maleimide, 3,4-dibromomaleimide, 6-Maleimidocaproic acid, and 4-maleimidobutyric acid.

3. The film according to claim 1, wherein the film has a single-layer structure, and the film comprises a mixture of the first modified material and the N-type semiconductor material.

4. The film according to claim 3, wherein a mass ratio of the first modified material to the N-type semiconductor material is (1-5):30.

5. The film according to claim 4, wherein the film comprises a mixture of the first modified material, the N-type semiconductor material, and a second modified material, and the second modified material comprises at least one of fulvalene and a fulvalene derivative.

6. The film according to claim 5, wherein a mass ratio of the first modified material to the N-type semiconductor material to the second modified material is (1-5):30:(1-5).

7. The film according to claim 5, wherein the fulvalene derivative comprises at least one of tetrathiafulvalene, dimethyltetrathiafulvalene, formyltetrathiafulvalene, 4,4′-diphenyltetrathiafulvalene, tetramethyltetraselenifulvalene, bis(trimethylenedithio) tetrathiafulvalene, and tetrakis (methylthio) tetrathiafulvalene.

8. The film according to claim 1, wherein the film comprises a first sublayer and a second sublayer stacked in this order, the first sublayer comprises the N-type semiconductor material, and the second sublayer comprises the first modified material.

9. The film according to claim 8, wherein a thickness ratio of the second sublayer to the first sublayer is (1-5):30.

10. The film according to claim 8, wherein the film comprise a third sublayer, a first sublayer and a second sublayer stacked in this order, the first sublayer comprises the N-type semiconductor material, the second sublayer comprises the first modified material, and the third sublayer comprises a second modified material, and the second modified material comprises at least one of fulvalene and a fulvalene derivative.

11. The film according to claim 10, wherein a thicknesses ratio of the third sublayer to the first sublayer to the second sublayer is (1-5):30:(1-5).

12. The film according to claim 10, wherein the fulvalene derivative comprises at least one of tetrathiafulvalene, dimethyltetrathiafulvalene, formyltetrathiafulvalene, 4,4′-diphenyltetrathiafulvalene, tetramethyltetraselenifulvalene, bis(trimethylenedithio) tetrathiafulvalene, and tetrakis (methylthio) tetrathiafulvalene.

13. The film according to claim 1, wherein the N-type semiconductor material comprises at least one of a metal oxide, a doped metal oxide, a Group II-VI semiconductor material, a Group III-V semiconductor material, and a Group I-III-VI semiconductor material.

14. The film according to claim 13, wherein the metal oxide is selected from at least one of ZnO, BaO, TiO₂, SnO₂; the metal oxide of the doped metal oxides is selected from at least one of ZnO, TiO₂, and SnO₂, and a doping element of the doped metal is selected from at least one of Al, Mg, Li, In, and Ga; the Group II-VI semiconductor material is selected from at least one of ZnS, ZnSe, and CdS; the Group III-V semiconductor material is selected from at least one of InP and GaP; the Group I-III-VI semiconductor material is selected from at least one of CuInS and CuGaS.

15. An optoelectronic device, comprising:
an anode and a cathode disposed oppositely;
N layers of light-emitting unit layers and N-1 layers of charge generating layers disposed between the anode and the cathode, and between each two adjacent light-emitting unit layers is disposed with one charge generating layer, where N is an integer equal to or greater than 2;
each light-emitting unit layer comprises a light-emitting layer and an electron-transporting layer stacked together, and the electron-transporting layer is disposed on a side of the light-emitting layer close to the cathode;
wherein at least one electron transport layer between the charge generating layer and the light-emitting layer comprises the film according to claim 1.

16. The optoelectronic device according to claim 15, wherein the optoelectronic device further comprises a hole injection layer and a hole transport layer stacked together, the hole injection layer and the hole transport layer are disposed between one of the light-emitting unit layers closest to the anode and the anode, and the hole transport layer is disposed on a side of the hole injection layer close to the cathode.

17. The optoelectronic device according to claim 16, wherein each of the charge generating layers comprises a hole generating layer and an electron generating layer stacked together, and in each of the charge generating layers, and the hole generating layer is disposed on a side of the electron generating layer close to the cathode.

18. The optoelectronic device according to claim 15, wherein the anode and the cathode independently comprise a doped metal oxide particle electrode, a composite electrode, a graphene electrode, a carbon nanotube electrode, a metal elemental electrode, or an alloy electrode; a material of the doped metal oxide particle electrode comprises one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, and aluminum-doped magnesium oxide; the composite electrode comprises one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS; a material of the metal elemental electrode comprises one or more of Ag, Al, Cu, Mo, Au, Pt, Ca, Mg, and Ba;
a material of each light-emitting layer independently comprises one or more of an organic light-emitting material and a quantum dot light-emitting material; the organic light-emitting material comprises one or more of 4,4′-bis(N-carbazole)-1,1′-biphenyl: tris[2-(p-tolyl) pyridinyl iridium (III), 4,4′,4″-tris(carbazol-9-yl) triphenylamine: tris [2-(p-tolyl) pyridinate iridium, diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, thermally activated delayed materials, polymers containing B-N covalent bonds, hybrid local charge transfer excited state materials, exciplex luminescent materials, polyacetylene and derivatives thereof, polyphenylene and derivatives thereof, polythiophene and derivatives thereof; the quantum dot light-emitting material comprises one or more of a single structure quantum dot, a core-shell structure quantum dot, and a perovskite semiconductor material; a material of the single structure quantum dot, a material of the core material of the core-shell structure quantum dot, and material of the shell material of the core-shell structure quantum dot are independently selected from one or more of a Group II-VI compound, a Group IV-VI compound, a Group III-V compound, and a Group I-III-VI compound; the Group II-VI compound comprises one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, and HgZnSTe; the Group IV-VI compound comprises one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, and SnPbSTe; the Group III-V compound comprises GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; the Group I-III-VI compound comprises one or more of CuInS₂, CuInSe₂, and AgInS₂; the perovskite-type semiconductor material comprises a doped or undoped inorganic perovskite-type semiconductor or an organic-inorganic hybrid perovskite-type semiconductor, the general structural formula of the inorganic perovskite-type semiconductor is AMX₃, wherein A is a Cs⁺ ion, M is a divalent metal cation comprising one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, and X is a halogen anion comprising one or more of Cl⁻, Br⁻, and I⁻; a general structural formula of the organic-inorganic hybrid perovskite type semiconductor is BMX₃, where B is an organic amine cation comprising CH₃(CH₂)ₙ₋₂NH₃⁺ or [NH₃(CH₂)ₙNH₃]²⁺, where n≥2, M is a divalent metal cation comprising one or more of Pb²⁺, Sn²⁺, Cu²⁺, Ni²⁺, Cd²⁺, Cr²⁺, Mn²⁺, Co²⁺, Fe²⁺, Ge²⁺, Yb², and Eu²⁺, and X is a halogen anion comprising one or more of Cl⁻, Br⁻, and I⁻.

19. The optoelectronic device according to claim 17, wherein a material of the hole transport layer comprises 4,4′-N,N′-dicarbazolyl-biphenyl, poly [bis(4-phenyl) (2,4,6-trimethylphenyl) amine], N,N′-diphenyl-N,N′-bis(1-naphthyl)-1,1′-biphenyl-4,4′-diamine, N,N′-diphenyl-N,N′-bis(3-methylphenyl)-4,4′-diamine, N′-bis(phenyl)-spiro, N,N′-bis(4-(N,N′-diphenyl-amino) phenyl)-N,N′-diphenylbenzidine, 4,4′,4′-tris (N-carbazolyl)-triphenylamine, 4,4′,4′-tris (N-3-methylphenyl-N-phenylamino) triphenylamine, poly [(9,9′-dioctylfluorene-2,7-diyl)-co-(4,4′-(N-(4-sec-butylphenyl)-co-(4,4′-(N-(4-sec-butylphenyl) diphenylamine)], poly(N-vinylcarbazole) and derivatives thereof, 1′-biphenyl-4-4′-diamine, spiro NPB, poly (phenylenevinylene), poly [2-methoxy-5-(2-ethylhexyloxy)-1,4-phenylenevinylene], poly [2-methoxy-5-(3′,7′-dimethyloctoxy)-1,4-phenylenevinylene], 2,2′,7,7′-tetrakis [N,N-bis(4-methoxyphenyl) amino]-9,9′-spirobifluorene, 4,4′-cyclohexylbis [N,N-bis(4-methylphenyl) aniline], 1,3-bis(carbazol-9-yl) benzene, polyaniline, polypyrrole, poly (P) phenylene vinylidene, aromatic tertiary amine, polynuclear aromatic tertiary amine, 4,4′-bis (P-carbazolyl)-1,1′-biphenyl compound, N,N,N′,N′-tetraarylbenzidine, PEDOT:PSS and derivatives thereof, polymethacrylates and derivatives thereof, poly (9,9-octylfluorene) and derivatives thereof, poly (spirofluorene) and derivatives thereof, poly (spirofluorene) and derivatives thereof, doped graphene, undoped graphene, undoped graphene, C60, doped or undoped NiO, doped or undoped MoO₃, doped or undoped WO₃, doped or undoped V₂O₅, doped or undoped P-type gallium nitride, doped or undoped CrO₃, and doped or undoped CuO;
a material of the hole injection layer and a material of each hole generating layer each independently comprise one or more of 2,3,6,7,10,11-hexacyano-1,4,5,8,9,12-hexaazabenzophenanthrene, PEDOT, PEDOT: PSS, a derivative of PEDOT: PSS doped s-MoO₃, 4,4′,4′-tris(N-3-methylphenyl-N-phenylamino) triphenylamine, tetracyanoquinodimethane, copper phthalocyanine, nickel oxide, molybdenum oxide, tungsten oxide, vanadium oxide, molybdenum sulfide, tungsten sulfide, and copper oxide.

20. A display device, comprising the optoelectronic device according to claim 15.
